(19) United States
(12) Patent Application Publication
(10) Pub. No.: US 2025/0253157 A1
(43) Pub. Date: Aug. 7, 2025

(54) METHOD FOR ETCHING A PATTERN IN A LAYER OF A SUBSTRATE

(71) Applicant: Tokyo Electron Limited, Tokyo (JP)

(72) Inventors: Hojin Kim, Albany, NY (US); Minseok Oh, Albany, NY (US); Minjoon Park, Albany, NY (US); Toru Hisamatsu, Albany, NY (US)

(21) Appl. No.: 18/430,313

(22) Filed: Feb. 1, 2024

(51) Int. Cl. H01L 21/311; H01L 21/033

(52) U.S. Cl. CPC H01L 21/31144; H01L 21/0332; H01L 21/31116

(57) ABSTRACT

A method for etching a pattern in a layer of a substrate includes holding the substrate in a plasma chamber, the substrate including a patterned tungsten silicon nitride (WxSiyNz) layer over a dielectric layer formed on an underlayer, the dielectric layer being a stack of alternating layers of silicon oxide and silicon nitride; flowing a gas over the substrate in the plasma chamber to provide a first flow of carbonyl sulfide (COS) at a first flow rate, a second flow of a perfluorocarbon (CxFy) at a second flow rate, and a third flow of oxygen (O₂) at a third flow rate; ionizing the gas in the plasma chamber to generate a plasma; and exposing the substrate to the plasma, the exposing selectively etching the dielectric layer with the pattern of the patterned WxSiyNz layer to form a patterned dielectric layer.

### TECHNICAL FIELD

The present invention relates generally to a method for semiconductor processing, and, in particular embodiments, to a method for etching a pattern in a layer of a substrate.

### BACKGROUND

Fabricating a semiconductor integrated circuit (IC) comprises integrating a network of electronic components in a monolithic structure. During fabrication, a batch of substrates is processed sequentially through a series of patterning levels comprising deposition and patterning processes, where, at each level, a pattern is transferred to targeted layers in the substrate using lithography and etch techniques. A new technology node is introduced about every two years, where the component density is doubled by shrinking feature sizes and using three dimensional (3D) devices, a combination that leads to fabricating very high aspect ratio structures. Many of the processing steps being plasma processes, plasma technology for forming 3D devices, such as 3D transistors, stacked dynamic random access memory (DRAM) and vertical NAND (V-NAND) memory, is challenged to etch the high aspect ratio structures with processes that meet stringent requirements for critical dimension (CD) control, local CD uniformity (LCDU), etch profile control, and manufacturing yield.

Recently, an insatiable demand for high density memory, created by a rapid growth of the mobile electronics market, is driving stacked DRAM and V-NAND technology to scale up the number of memory cells stacked vertically. Since the vertical scaling is limited by an ability to etch high aspect ratio holes through a molding layer used to stack the memory cells, further innovations in plasma etching methods for high aspect ratio structures is desirable.

### SUMMARY

A method for etching a pattern in a layer of a substrate includes holding the substrate in a plasma chamber, the substrate including a patterned tungsten silicon nitride (WxSiyNz) layer over a dielectric layer formed on an underlayer, the dielectric layer being a stack of alternating layers of silicon oxide and silicon nitride; flowing a gas over the substrate in the plasma chamber to provide a first flow of carbonyl sulfide (COS) at a first flow rate, a second flow of a perfluorocarbon (CxFy) at a second flow rate, and a third flow of oxygen (O2) at a third flow rate; ionizing the gas in the plasma chamber to generate a plasma; and exposing the substrate to the plasma, the exposing selectively etching the dielectric layer with the pattern of the patterned WxSiyNz layer to form a patterned dielectric layer.

A method for etching a pattern in a layer of a substrate includes holding the substrate in a plasma chamber, the substrate including a patterned tungsten silicon nitride (WxSiyNz) layer over a dielectric layer formed on an underlayer, the dielectric layer being a stack of alternating layers of silicon oxide and silicon nitride; flowing a gas over the substrate in the plasma chamber to provide a first flow of a halogen-free sulfur compound at a first flow rate, a second flow of a fluorocarbon at a second flow rate, and a third flow of oxygen (O2) at a third flow rate; ionizing the gas in the plasma chamber to generate a plasma; and exposing the substrate to the plasma, the exposing selectively etching the dielectric layer with the pattern of the patterned WxSiyNz layer to form a patterned dielectric layer.

A method for etching a pattern in a layer of a substrate includes holding the substrate in a plasma chamber, the substrate including a patterned tungsten silicon nitride (WxSiyNz) layer over a dielectric layer formed on an underlayer; flowing a gas over the substrate in the plasma chamber to provide a first flow of carbonyl sulfide (COS) at a first flow rate, a second flow of a perfluorocarbon (CxFy) at a second flow rate, and a third flow of oxygen (O2) at a third flow rate; ionizing the gas in the plasma chamber to generate a plasma; and exposing the substrate to the plasma, the exposing selectively etching the dielectric layer with the pattern of the patterned WxSiyNz layer to form a patterned dielectric layer.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates a flowchart of a method for etching a pattern in a layer of a substrate, in accordance with an embodiment of the invention;

FIGS. 2A-2B illustrate cross-sectional views of a substrate at various intermediate stages of processing, in accordance with an embodiment of the invention;

FIG. 3 illustrates a cross-sectional view of a plasma processing system, in accordance with an embodiment of the invention; and

FIGS. 4A-4B illustrate various cross-sectional views of a substrate at various intermediate stages of processing, in accordance with an embodiment of the invention.

### DETAILED DESCRIPTION OF ILLUSTRATIVE EMBODIMENTS

The disclosure describes methods for transferring a pattern from a patterned etch mask layer to a layer of a substrate using plasma etch processes that provide an advantage of improved local critical dimension uniformity (LCDU) along with an advantage of selectively etching the layer being patterned with a higher selectivity. Here, etch selectivity refers to a ratio of an etch rate of the layer being patterned to an etch rate of the patterned etch mask layer.

In the embodiments described in this disclosure, the layer being patterned is a dielectric layer of the substrate formed on an underlayer, and the etch mask layer is a tungsten silicon nitride (WxSiyNz) layer formed over the dielectric layer and patterned with a pattern of openings. The pattern is transferred to the dielectric layer when the substrate is exposed to a plasma that selectively etches the dielectric layer. In some embodiments, the plasma etching forms holes through the dielectric layer to expose a surface of the underlayer. In some embodiments, the underlayer comprises a material which has a low etch rate relative to an etch rate of the dielectric layer after the underlayer is exposed. In some embodiments, the etch process may be designed to also etch the underlayer and stop on a layer underneath the underlayer.

In some embodiments, the dielectric layer may be a stacked dielectric layer comprising layers of multiple dielectrics, for example, a stack of alternating layers of silicon oxide and silicon nitride (sometimes referred to as an ON stacked dielectric layer).

In some other embodiments, the dielectric layer may comprise a major dielectric layer. For example, the dielectric layer may be an interlayer dielectric (ILD) layer, where the ILD layer includes a major dielectric layer comprising a low-k silicon oxide. In some instances, the dielectric layer may include a minor layer. For example, the ILD layer may include an etch stop layer comprising silicon oxynitride inserted in the major dielectric layer comprising the low-k silicon oxide.

The underlayer adjacent below the dielectric layer may comprise various materials in various embodiments, depending on the semiconductor device being fabricated.

In some embodiments, the underlayer may be an etch stop layer, and the etch stop layer may comprise an insulator or a conductor. For example, the insulating etch stop layer may comprise silicon carbide, silicon nitride, or the like, and the conductive etch stop layer may comprise titanium silicide, titanium nitride, or the like.

In some embodiments, where the dielectric layer is an ON stacked dielectric layer, the underlayer may comprise an insulator, such as silicon nitride.

In some other embodiments, where the dielectric layer is an ON stacked dielectric layer, the underlayer may comprise a semiconductor, such as silicon or germanium. The semiconductor comprising silicon may be, for example, polysilicon, a silicon-germanium alloy, or the like.

In some embodiments, the dielectric layer may be an interlayer dielectric (ILD) layer formed over an interconnect level, as mentioned above. In this instance, the layer below the ILD layer, i.e., the underlayer, may include a portion comprising a conductor of the interconnect level, while another portion may comprise an insulator of the interconnect level comprising, for example, another low-k silicon oxide layer of another ILD layer.

The layers of the substrate below the underlayer may be collectively referred to as a semiconductor substrate. The semiconductor substrate may comprise bulk crystalline silicon, silicon-on-insulator (SOI), crystalline germanium, compound semiconductor (e.g., GaAs, InP, and InAs), semiconductor alloy (e.g., SiₓGe₁₋ₓ, GaₓAl_{y}As_{1-x-y}), and the like.

The invention is first described using an example embodiment of a method for a pattern transfer plasma etch, where a pattern of holes is etched through an ON stacked dielectric layer of a substrate. As explained below, by using the example embodiment described in this disclosure, it may be possible to improve an LCDU of the pattern of holes and increase etch selectivity, both of which are advantageous to fabrication of high density nonvolatile memory (NVM) devices.

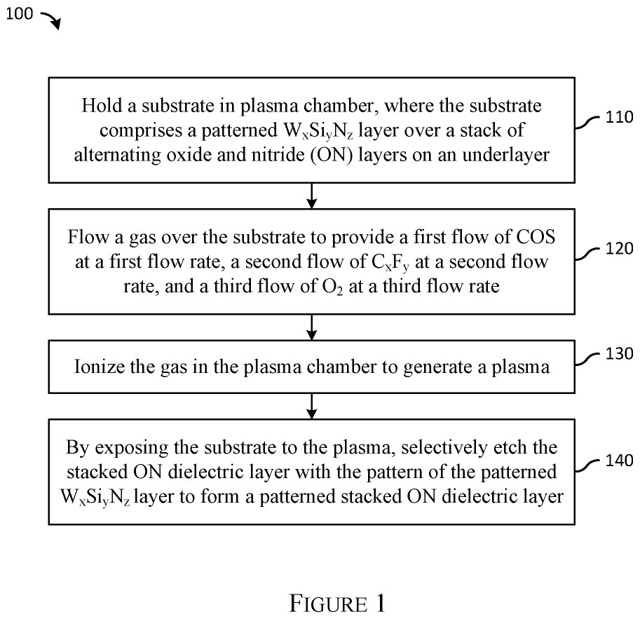

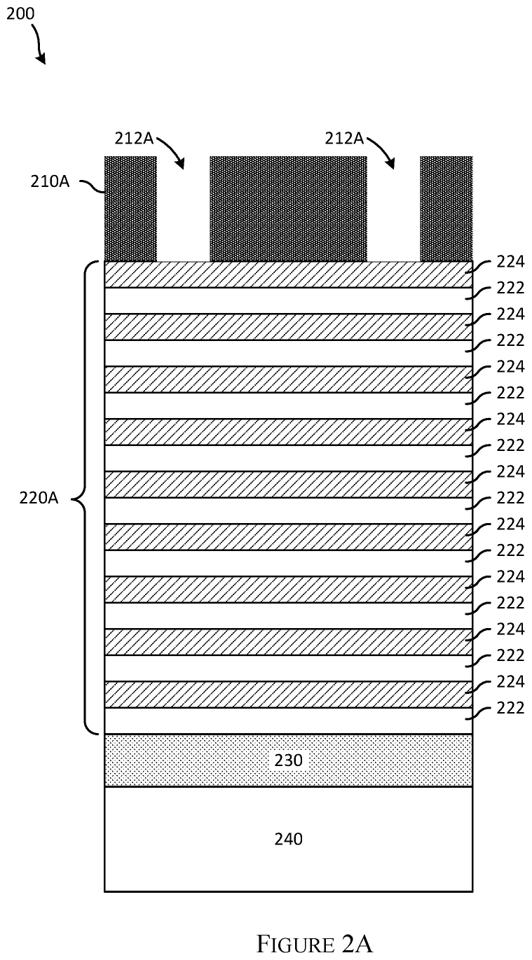

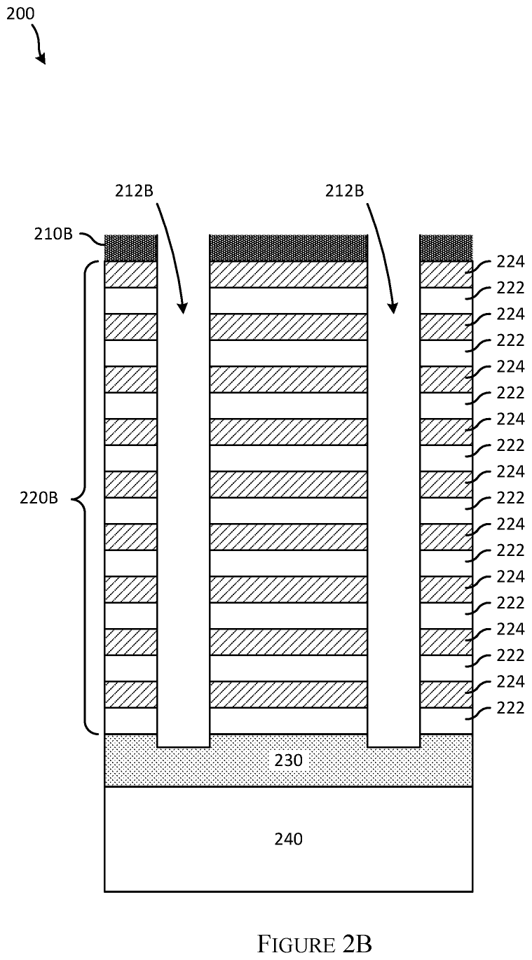

FIG. 1 illustrates a flowchart for the example method 100, and FIG. 2A shows a cross-sectional view of the substrate 200 prior to performing the pattern transfer etch. As indicated in box 110 of the flowchart in FIG. 1 and illustrated in FIG. 2A, the substrate 200 comprises a patterned WₓSi_{y}N_{z} layer 210A to be used as a patterned etch mask layer over the layer to be patterned. The pattern of the patterned WₓSi_{y}N_{z} layer 210A comprises, for example, a pattern of holes 212A. The layer to be patterned is an ON stacked dielectric layer 220A, which is a stack of alternating layers of silicon oxide 222 and silicon nitride 224. The ON stacked dielectric layer 220A has been formed over an underlayer 230. Layers of the substrate 200 below the underlayer 230 is represented by a semiconductor substrate 240 in FIG. 2A.

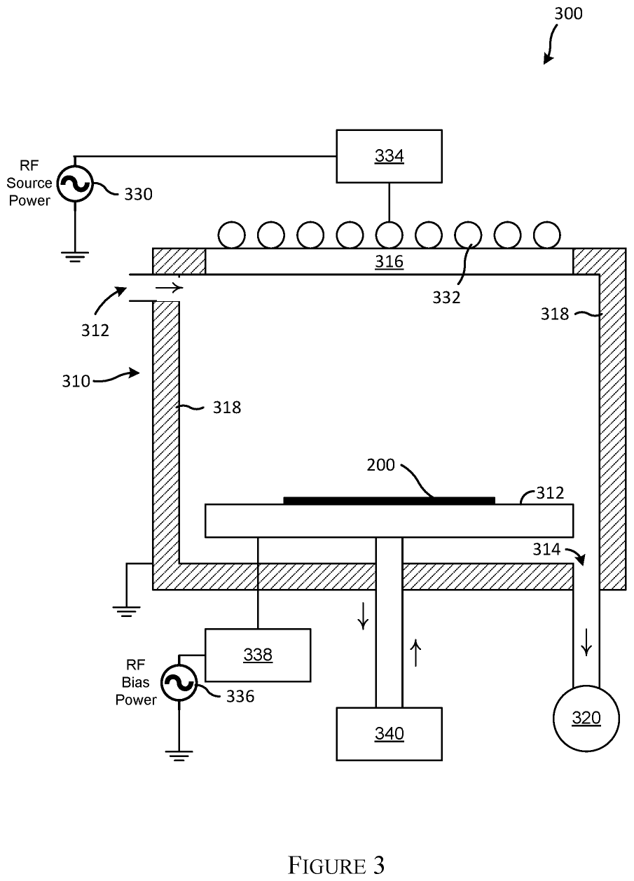

FIG. 2B illustrates a cross-sectional view of the substrate 200 after the pattern of holes 212A (as illustrated in FIG. 2A) has been transferred to form a patterned dielectric layer 220B. In an embodiment, the pattern transfer may be achieved by executing the method 100, described by the flowchart, illustrated in FIG. 1. In method 100, a plasma etch technique is used in patterning the ON stacked dielectric layer 220A. Thus, the substrate 200 is held in a plasma chamber of a plasma processing system, as indicated by box 110 in the flowchart for method 100. FIG. 3 illustrates a schematic of an example plasma processing system 300, where a plasma chamber 310 is shown in a cross-sectional view. In FIG. 3, the substrate 200 is seen positioned on a pedestal 312 in a lower portion of the plasma chamber 310. The pedestal 312 may comprise an electrostatic chuck configured to hold a backside of the substrate 200 placed over the pedestal 312, while a side of the substrate 200 opposite the backside is exposed to the ambient inside the plasma chamber 310.

The plasma chamber 310 (illustrated in FIG. 3) is a vacuum chamber coupled to a gas flow system via a gas inlet 312 and a gas outlet 314. In general, there may be multiple gas inlets and outlets. A vacuum pump 320, coupled to the gas outlet 314, may be operated to flow a gas comprising process and diluent gases over the substrate 200 in the plasma chamber 310 at a controlled low pressure. The gaseous mixture may be introduced into the plasma chamber 310 through a gas flow line of the gas flow system. Although not shown, the gas flow system may include gas canisters, throttle valves, flow meters, pressure sensors, and the like to maintain a controlled gas flow in the plasma chamber 310.

As indicated in box 120 in the flowchart for method 100, the controlled gas flow through the plasma chamber 310 comprises a first flow of carbonyl sulfide (COS) at a first flow rate, a second flow of a perfluorocarbon (CₓF_{y}) at a second flow rate, and a third flow of oxygen (O₂) at a third flow rate. The vacuum pump 320 may be configured to maintain the plasma chamber 310 at a controlled pressure, where the controlled chamber pressure is from about 0.001 Torr to about 1_Torr, in various embodiments. The first flow rate (i.e., the flow rate of COS) may be from 3 sccm to 5 sccm, in some embodiments, and greater than or equal to 1 sccm and less than or equal to 10 sccm, in various embodiments. The perfluorocarbon in the second flow may be CF₄, C₂F₆, C₃F₈, C₄F₆, or c-C₄F₈, for example CF₄ in one embodiment. In one embodiment, the first flow rate, the second flow rate, and the third flow rate are in a ratio of 1:20:10. In various embodiments, a ratio of the first flow rate to the second flow rate may be between about 1:10 and 1:30, and a ratio of the first flow rate to the third flow rate may be between about 1:5 and 1:15. In addition, there may be a flow of an inert gas, such as argon or krypton. For example, the controlled gas flow may include a flow of argon at a flow rate of about 10 sccm to about 200 sccm.

In box 130 in the flowchart for method 100, the gas introduced into the plasma chamber 310 is ionized to generate a plasma over the substrate 200. The plasma is a glow discharge, ignited and sustained using electromagnetic (EM) power from radio frequency (RF) and DC (or pulsed DC) power sources coupled to electrodes that are configured to generate EM fields inside the plasma chamber 310. In some embodiments, the plasma processing system is configured in an inductively coupled plasma (ICP) mode, where RF power is coupled inductively to the plasma. For example, in the plasma processing system 300, a first RF power source 330 is coupled to a first electrode 332. Here, the first electrode 332 is an antenna shaped as a planar coil disposed over a top portion of the plasma chamber 310, indicated as a dielectric window 316. A first impedance matching circuit 334 is inserted in the signal path between the first RF source 330 and the first electrode 332 to suppress reflections and to improve a power transfer efficiency to the plasma. As illustrated schematically in FIG. 3, a second RF power source 336 is coupled, via a second impedance matching circuit 338, to a second electrode, which is a disk-shaped conductive part of the pedestal 312. In this configuration, the first electrode 334 provides RF source power and the second electrode (in the pedestal 312) provides RF bias power to the plasma. In some embodiments, bias power supplied to the second electrode may comprise EM power from a pulsed DC source. As known to persons skilled in the art, having two independent EM power sources coupled to the plasma provides independent control over a supply of radicals and a directed kinetic energy of ions to the substrate 200, which controls anisotropy of the plasma etch process.

In the example method 100, the RF source power from the first RF power source 330 may be from about 0.1 kW to about 10 KW in a frequency range of about 10 MHz to about 4 GHZ, and the RF bias power from the second RF power source 336 may be from about 0.5 kW to about 50 kW in a frequency range of about 0.1 MHz to about 100 MHz. For example, in one embodiment, the RF source power may be 2.0 kW at a frequency of 50 MHz, and the RF bias power may be 20 kW at a frequency of 0.5 MHz.

As indicated in box 140 in the flowchart for method 100, the ON stacked dielectric layer 220A of the substrate 200 in FIG. 2A is selectively etched with the pattern of the patterned WₓSi_{y}N_{z} layer 210A by exposing the substrate 200 to the plasma. The plasma process parameters, described above, may be selected to perform an anisotropic reactive ion etch (RIE) that transfers the pattern of the etch mask layer (i.e., the WₓSi_{y}N_{z} layer 210A) to the layer being patterned (i.e., the ON stacked dielectric layer 220A) to form a respective patterned layer. The RIE process removes material chemically, but RIE also has a physical component due to the impact of ions with high kinetic energy on the exposed surface. The impact not only removes material by sputtering, but also increases the chemical reaction rate by displacing material from the impacted surface. Thus, a vertical flux of ions bombarding a bottom surface of the openings results in a faster vertical etch rate relative to a lateral etch rate.

Chemical reactions being sensitive to temperature, the plasma system 300 is equipped with a thermal system 340 configured to maintain the substrate 200 at a controlled temperature. The pedestal 312 comprises a platen supported by a stem, as illustrated in FIG. 3. The thermal system 340 may comprise liquid coolant, cooling gas, pumps, heater elements, power supplies, and temperature sensors. The thermal system 340 may be configured with pipes and gas flow lines accessing the platen through the stem of the pedestal 312 in order to circulate the coolant within the pedestal 312 and flow the cooling gas through grooves in the platen along the backside of the substrate 200. Electrical heater elements may be placed within the pedestal 312 proximate the backside of the substrate 200 and coupled to the power supplies of the thermal system 340.

The plasma processing system 300 may include a controller comprising a processor and memory storing instructions and data to control the plasma process parameters, described above. Process parameters, such as the flow rates, the substrate temperature, and the RF signals may be specified in a process recipe loaded to the memory and controlled by control signals transmitted from the controller to various components of the plasma processing system 300.

In the example embodiment, the etch mask comprises a pattern of holes 212A. The resulting patterned dielectric layer 220B is illustrated in FIG. 2B. As illustrated in FIG. 2B, the anisotropic RIE has extended the holes 212A, forming a pattern of holes 212B through the patterned dielectric layer 220B and exposing a surface of the underlayer 230. In some other embodiment, the etching may be terminated earlier, for example, when trenches are etched in an ILD layer to form metal lines of an interconnect level.

The anisotropic RIE process alternately removes silicon oxide and silicon nitride from the alternating layers of silicon oxide 222 and silicon nitride 224 with fluorine chemistry using fluorine radicals obtained from the perfluorocarbon. Fluorine radicals being highly reactive, it is difficult to select a combination of masking material and etchant gas that would be an effective etch mask during an anisotropic etch process used for vertically etching deep and narrow openings in a dielectric layer, such as the ON stacked dielectric layer 220A in FIG. 2A.

In this disclosure, for an etch mask to be an effective etch mask, it is not sufficient for the etch mask to provide a high etch selectivity to prevent patterning defects due to excessive loss in thickness. In addition, the etch mask has to provide smooth sidewall profiles of the patterned features such that the pattern of openings has a low LCDU in the patterned dielectric layer (e.g., the patterned dielectric layer 220B). Generally, improving the LCDU of a feature of an electronic device reduces random variations in its electrical characteristics and provides better matching of identically designed devices. Here, a low LCDU provides an advantage of low random variability in electrical characteristics of electronic components formed in the holes. For example, the holes may be subsequently filled with material comprising conductors, and a high LCDU would cause undesirable random variations in electrical resistance of the conductor in the hole.

As known to persons skilled in the art, LCDU is a measure of the roughness along the edges of the openings, generally defined as three times an RMS value of random variations in a width of the openings. There are several techniques for measuring LCDU. For example, the LCDU may be obtained from random variations in diameter along a circumference of each hole of the pattern of holes 212B in the patterned dielectric layer 220B. Likewise, the LCDU may be obtained from width variations along a short distance, which is equivalent to a measured spectral density of width variations at a high spatial frequency. Alternatively, LCDU can be obtained using mismatch in widths of identically designed pairs of features.

Yet another aspect of pattern quality (in addition to CD and LCDU) is reproducing a shape of the etch feature with high fidelity. For example, the more the shape of a circular hole deviates from the symmetry of the circle the worse is the fidelity with which the circular hole has been patterned. A commonly used metric for circular openings is its circularity, defined as a ratio of a minimum diameter to a maximum diameter of the opening. An ideal circle has circularity equal to one. For most applications, an average circularity of 0.9 or greater is desired.

As mentioned above, since the underlayer 230 is exposed by the holes 212B, it is desired that, after the underlayer 230 is exposed, the exposed material has a low etch rate relative to an etch rate of the patterned dielectric layer 220B so that the etching may stop on the underlayer 230. For the sake of specificity, the underlayer 230 in the example embodiment in FIG. 2B may comprise silicon nitride. In some embodiments, an endpoint signal may be generated by exposing the underlayer 230. The endpoint signal may be detected by a sensor and the data provided to the controller, which then initiates a termination of the anisotropic RIE process. In some embodiments, during the etch termination process, the etched holes 212B may extend a bit further and recess the exposed surface of the underlayer 230, as illustrated in FIG. 2B. In various embodiments, a ratio of the etch rate of the patterned dielectric layer 220B to the etch rate of the underlayer 230 may be in the range of 1 to 100 and about 50 in one embodiment. In some embodiments, the etch process may be designed to also etch the underlayer 230 and stop on the layer underneath the underlayer 230.

As known to persons skilled in the art, scaling bit density of a memory device, for example, a dynamic random access memory (DRAM) or a nonvolatile memory (NVM), by shrinking a planar cell is limited by increased charge leakage resulting in data corruption and reliability degradation. Three dimensional (3D) scaling by layering memory cells in a vertical direction has proven to be a more viable approach to scaling, thus leading to stacked DRAM and vertical NAND (V-NAND) architectures having an ever increasing number of memory cells integrated in each vertical stack.

Stacked dielectric layers are often used in the fabrication of three-dimensional (3D) memory ICs. For example, in some embodiments, an ON stacked dielectric layer, similar to the ON stacked dielectric layer 220A in FIG. 2A, may be used as a mold stack to form the layered cells of a DRAM based on a stacked gate architecture. In various embodiments, the number of layers in the ON stacked dielectric layer may be from about 50 to about 500. A thickness of each layer of silicon oxide 222 may be similar to that of each layer of silicon nitride 224. In some embodiments, the thickness of each layer may be between about 10 nm and about 400 nm in various embodiments. A pattern of openings (e.g., holes) similar to the pattern of holes 220B, may be etched in the mold stack to fabricate the memory cells. Each opening has a width dimension (e.g., a diameter of a circular hole) and a depth dimension, where a ratio of the depth to the width is the aspect ratio of the opening. In various embodiments, the average aspect ratio of the holes in the pattern of holes 220B may be from about 50 to about 200. In various embodiments, a diameter of each hole of the pattern of holes 220B may be between about 10 nm and about 100 nm in various embodiments. In some embodiments, the holes of the pattern of holes 220B may be subsequently filled, for example, with doped polysilicon to be used as channels of vertically layered memory cells.

Generally, scaling cell density of memory ICs, including that of DRAM ICs, may be limited by an ability to etch high aspect ratio holes through the mold stack used for layering memory cells. In this context, high aspect ratio refers to aspect ratios exceeding about 50. It is advantageous for an etch process used in etching high aspect ratio holes in an ON stacked dielectric layer to remove the dielectric materials with high selectivity to the respective etch mask. An effective etch mask has not only high etch selectivity but also provides a low LCDU of the features in the etched pattern. As known to persons skilled in the art, identifying an appropriate combination of etchant and etch mask material is difficult. For example, with a gaseous mixture comprising NF₃, CₓF_{y}, and O₂ as the process gas for an anisotropic RIE process to etch high aspect ratio holes in the ON stacked dielectric layer 220A, the etch selectivity is higher if an etch mask comprising boron-doped silicon is replaced with a tungsten silicide etch mask. However, inventors of this application found that the LCDU of the etched pattern was worse than the low LCDU of patterns etched using the boron-doped silicon hardmask. In further experiments performed by the inventors, it is seen that the increased LCDU, observed earlier in patterns etched using the tungsten silicide hardmask, may be reduced back down to be similar to that achieved using the boron-doped silicon hardmask if the hardmask material is altered from tungsten silicide to tungsten silicon nitride (WₓSi_{y}N_{z}). But the low LCDU was achieved at the cost of a higher rate of loss of hardmask material, i.e., a lower etch selectivity.

A theoretical analysis done by the inventors revealed that the etch selectivity may be reduced because the hardmask material has a different chemical reaction with nitrogen in the plasma (from the NF₃). Calculations of formation energies suggest that in a chemical reaction between nitrogen and tungsten silicide, nitrogen bonds preferentially with tungsten in tungsten silicide. By bonding to tungsten, the nitrogen protects the fluorine radicals from reacting with tungsten. In contrast, the calculated formation energies suggest that in a chemical reaction between nitrogen and tungsten silicon nitride, nitrogen bonds preferentially with another nitrogen in the tungsten silicon nitride, thus leaving the tungsten exposed to react with fluorine radicals in the plasma and yield a volatile byproduct such as tungsten hexafluoride. This may enhance the removal rate of tungsten silicon nitride, hence reduce the etch selectivity of the hardmask. On the other hand, oxygen and carbon both bond preferentially with tungsten in their respective chemical interaction with tungsten silicon nitride. Further calculations by the inventors revealed that sulfur bonds preferentially with tungsten when chemically reacted with tungsten silicon nitride.

The theoretical analysis, described above, suggests that the removal rate of tungsten silicon nitride may be reduced (i.e., the etch selectivity may be increased) if (a) a gaseous sulfur compound is included in the process gas, and (b) if NF₃ (or some other nitrogen compound) in the process gas is reduced or eliminated. Accordingly, further experiments have been performed by the inventors, where the plasma to which the substrate 200 is exposed is generated by ionizing the gas in a controlled gas flow comprising a first flow of carbonyl sulfide, a second flow of a perfluorocarbon, and a third flow of oxygen, as described above. By exposing the substrate 200 to the plasma, the ON stacked dielectric layer 220A is selectively etched using the patterned WₓSi_{y}N_{z} as the etch mask.

In various embodiments, the etch selectivity for this etch process is at least about 4 and, in some embodiments, between 4 and 10 and 6 in one embodiment. As mentioned above, in this context, etch selectivity refers to a ratio of the etch rate of the ON stacked dielectric layer 220A to the etch rate of the patterned WₓSi_{y}N_{z} layer 210A. Furthermore, a typical LCDU achieved by this etch process is about 1.5 nm. In various embodiments, the LCDU of features patterned using this etch process may be less than or equal to about 2 nm and, in some embodiments, as low as about 1 nm. The average circularity achieved for this process may be greater than or equal to about 0.9 and less than or equal to 1.

It is noted that it is desirable for the sulfur compound to be a halogen-free sulfur compound because an excessive amount of halogens in the plasma may degrade the etch selectivity recovered by the use of sulfur. Accordingly, in some embodiments, a gas such as sulfur dioxide (SO₂) and hydrogen sulfide (H₂S), which comprises sulfur but is free of halogens, may be included in the gaseous mixture in the plasma chamber 310.

In the embodiments, described above, the source of fluorine is a perfluorocarbon (CₓF_{y}). However, it is understood that a hydrofluorocarbon (CₓH_{y}F_{1-x-y}) may also be included in the gaseous mixture as a source of fluorine.

The higher selectivity of the plasma etch processes in the embodiments, described in this disclosure, allows using a thinner etch mask layer since less masking material is lost during etching, and using a thinner etch mask layer is advantageous because the high aspect ratios of narrow openings is lowered by reducing a height of the masking layer. Furthermore, higher selectivity enables increasing a maximum depth to which openings may be etched without increasing a thickness of the etch mask layer. This may be advantageous when the thickness of the patterned etch mask layer used to etch the layer being patterned is limited by a maximum resist layer thickness of the lithography process used to pattern the etch mask layer. The maximum resist layer thickness has been reducing with scaling, a trend driven mainly by a higher risk of resist collapse in high aspect ratio resist features and an increased defectivity due to stochastic effects in resist patterned at nanometer scale pitches with extreme ultraviolet (EUV) lithography.

The stochastic effects arise because of a 15-fold increase in photon energy of the EUV radiation used to expose resist whenever critical patterning at the sub-10 nm technology nodes is transitioned from deep ultraviolet (DUV) 193 nm wavelength immersion (193i) lithography to 13 nm wavelength EUV lithography. Typically, the total doses for EUV and DUV radiation are similar since increasing the exposure dose causes undesirable heating as well as longer exposure time (hence higher manufacturing cost). Accordingly, a count of photons per unit area to which resist is exposed in EUV lithography is one-fifteenth of that for DUV. The total number of photons, i.e., the total exposure dose, within a finite area of resist is inherently a stochastic process, causing undesired random variations in the resist pattern of each feature in a set of identically designed features. The smaller the feature, the larger is the impact of random variations. The percentage variation in exposure dose is magnified by the greatly reduced number of photons used to expose resists with EUV radiation. The random variations may even cause defects, such as line breaks and bridging, in the resist pattern. As known to persons skilled in the art, the stochastic effects become worse with increasing resist thickness. Thus, the resist thickness may be limited to a maximum value to keep both structural instabilities and stochastic effects in control.

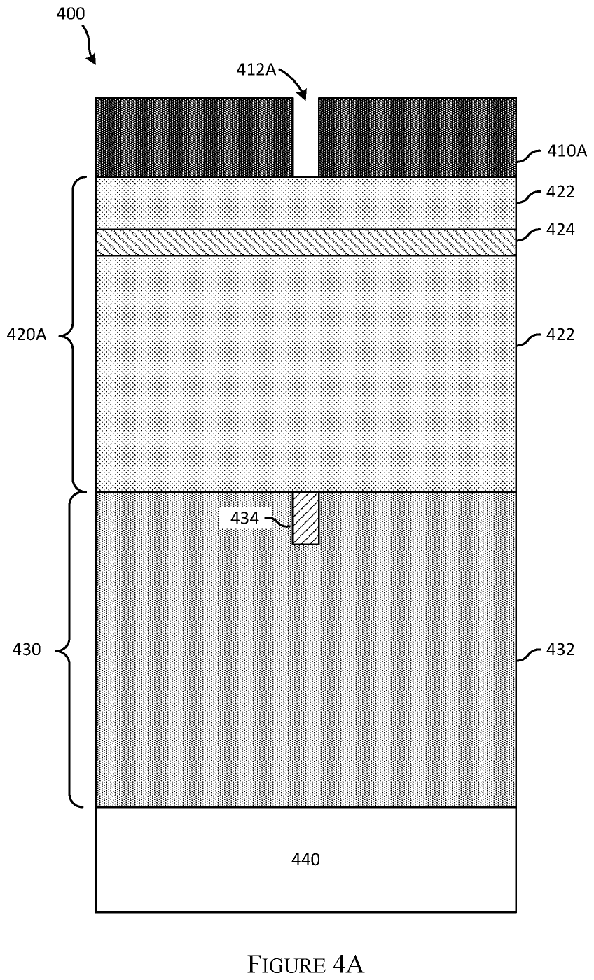

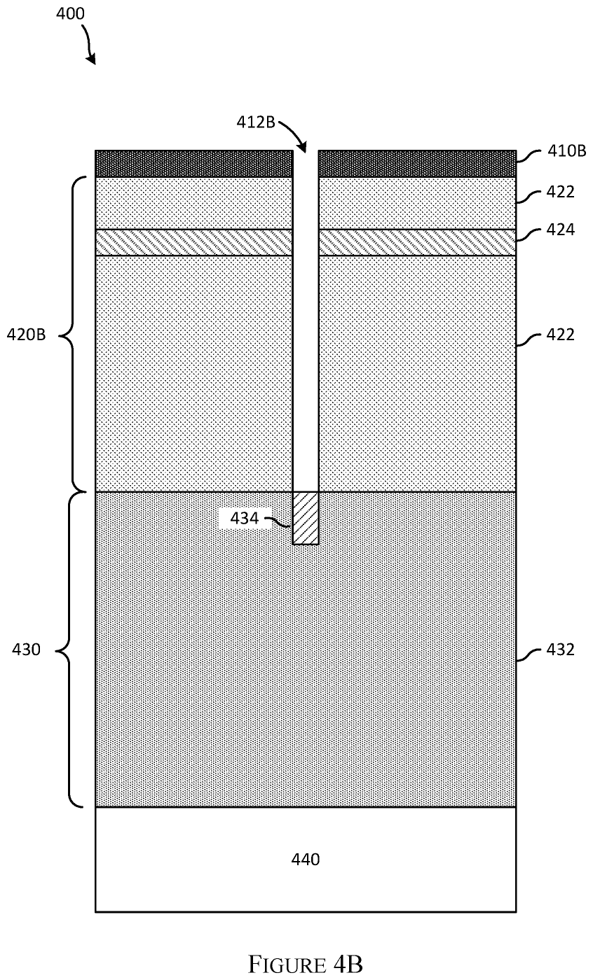

As mentioned above, in some embodiments, the dielectric layer being patterned may not be a stacked dielectric layer. Instead the dielectric layer being patterned may comprise a major dielectric layer. In some instances, the major dielectric layer may include a minor layer such as an etch stop layer. FIGS. 4A-4B illustrate cross-sectional views of a substrate 400.

In FIG. 4A, the substrate 400 comprises a patterned etch mask layer 410A formed over the major dielectric layer 420A. The patterned etch mask layer 410A may comprise WₓSi_{y}N_{z}. The major dielectric layer 420A, which is the dielectric layer to be patterned, may be an upper interlayer dielectric (ILD) layer of an upper interconnect level formed over a vertically adjacent lower interconnect level 430. The patterned etch mask layer 410A has a pattern of holes 412A that replicates a pattern of via holes to be formed in the major dielectric layer 420A.

The major dielectric layer 420A comprises a low-k silicon oxide layer 422 and the minor layer 424. The low-k silicon oxide layer 422 may comprise a low-k silicon oxide, such as carbon-doped silicon oxide or porous silicon oxide. The minor layer 424 may be an etch stop layer used in a subsequent patterning level to form trenches for metal lines of the upper interconnect level. The minor layer 424 may comprise, for example, silicon oxynitride or silicon nitride.

The lower interconnect level 430 comprises a lower ILD layer 432 and lower metal lines 434. The lower ILD layer 432 may comprise a low-k silicon oxide, such as carbon-doped silicon oxide or porous silicon oxide. The lower metal lines 434 may comprise a metal, for example, copper, ruthenium, molybdenum, and the like.

In this example embodiment, the layer of the substrate 400 adjacent below the major dielectric layer 420A is the lower interconnect level 430. Accordingly, the underlayer, in this example, is the lower interconnect level 430. Thus, one portion of the underlayer comprises the conductive lower metal lines 434 and another portion of the underlayer comprises the insulating lower ILD layer 432. The layers of the substrate 400 below the lower interconnect level 430 may be collectively referred to as a semiconductor substrate.

FIG. 4B illustrates the substrate 400 after the major dielectric layer 420A has been etched to form the patterned major dielectric layer 420B. The etch process may be similar to the anisotropic RIE process in method 100, described above with reference to FIG. 1, FIGS. 2A-2B, and FIG. 3. As illustrated in Figure-4B, a portion of the patterned etch mask layer 410A has been removed, resulting in the thinner patterned etch mask layer 410B, as illustrated in FIG. 4B.

In this embodiment, the pattern of holes 412A has been extended through the major dielectric layer 420A to form the patterned major dielectric layer 420B. In the example, illustrated in FIG. 4B, the bottom of the holes of the pattern of holes 412B exposes a conductive surface of the lower metal lines 434. Subsequently, the holes of the pattern of holes 412B would be filled with copper and damascened to form conductive vias.

Typically, the design rules are set aggressively such that a minimum width of the lower metal lines 434 is same as a width of a via, i.e., a width of the holes of the pattern of holes 412B. Thus, in some instances, because of misalignment and CD variation, some holes of the pattern of holes expose a surface of the insulating lower ILD layer 432. Thus, in general, etching the major dielectric layer 420A to form the patterned major dielectric layer 420A may expose the surface of a conductor and a surface of an insulator.

In this disclosure we have described embodiments of methods for transferring the pattern from a patterned etch mask to form a patterned dielectric layer. The methods may be used advantageously to form high aspect ratio openings in various dielectric layers with high etch selectivity and low LCDU. The advantages provided by the embodiments may be exploited to form vertically conductive structures with reduced variability in their electrical characteristics, which is useful in fabricating high aspect ratio vias connecting vertically adjacent interconnect lines high aspect ratio vertical channels in high bit density V-NAND memory.

Example embodiments of the invention are described below. Other embodiments can also be understood from the entirety of the specification as well as the claims filed herein.

Example 1. A method for etching a pattern in a layer of a substrate includes holding the substrate in a plasma chamber, the substrate including a patterned tungsten silicon nitride (WxSiyNz) layer over a dielectric layer formed on an underlayer, the dielectric layer being a stack of alternating layers of silicon oxide and silicon nitride; flowing a gas over the substrate in the plasma chamber to provide a first flow of carbonyl sulfide (COS) at a first flow rate, a second flow of a perfluorocarbon (CxFy) at a second flow rate, and a third flow of oxygen (O2) at a third flow rate; ionizing the gas in the plasma chamber to generate a plasma; and exposing the substrate to the plasma, the exposing selectively etching the dielectric layer with the pattern of the patterned WxSiyNz layer to form a patterned dielectric layer.

Example 2. The method of example 1, where a ratio of the first flow rate to the second flow rate is between 1:10 and 1:30, and where a ratio of the first flow rate to the third flow rate is between 1:5 and 1:15.

Example 3. The method of one of examples 1 or 2, where the first flow rate is greater than or equal to 3 sccm and less than or equal to 5 sccm.

Example 4. The method of one of examples 1 to 3, where selectively etching the dielectric layer includes etching the dielectric layer with a first etch rate and etching the patterned WxSiyNz layer with a second etch rate, a ratio of the first etch rate to the second etch rate being greater than or equal to 4 and less than or equal to 10.

Example 5. The method of one of examples 1 to 4, where the underlayer includes silicon nitride.

Example 6. The method of one of examples 1 to 5, where selectively etching the dielectric layer exposes a surface of the underlayer, and where, after a surface of the underlayer is exposed, a ratio of an etch rate of the dielectric layer to an etch rate of the underlayer is greater than or equal to 1 and less than or equal to 100.

Example 7. The method of one of examples 1 to 6, where exposing a surface of the underlayer generates an endpoint signal which, when detected, initiates a termination of etching the dielectric layer.

Example 8. The method of one of examples 1 to 7, where an opening in the patterned dielectric layer has a width dimension and a depth dimension, the width being between 10 nm and 100 nm, and a ratio of the depth to the width being greater than 50 and less than 200.

Example 9. The method of one of examples 1 to 8, where the patterned dielectric layer has a plurality of openings, each opening shaped like a circle having a circularity defined as a ratio of a minimum diameter to a maximum diameter of the opening, the plurality of openings having an average circularity greater than or equal to 0.9 and less than or equal to 1.

Example 10. The method of one of examples 1 to 9, where the patterned dielectric layer has a plurality of openings, each opening having a fixed designed width, the plurality of openings having a local critical dimension uniformity (LCDU) greater than or equal to 1 nm and less than or equal to 2 nm.

Example 11. A method for etching a pattern in a layer of a substrate includes holding the substrate in a plasma chamber, the substrate including a patterned tungsten silicon nitride (WxSiyNz) layer over a dielectric layer formed on an underlayer, the dielectric layer being a stack of alternating layers of silicon oxide and silicon nitride; flowing a gas over the substrate in the plasma chamber to provide a first flow of a halogen-free sulfur compound at a first flow rate, a second flow of a fluorocarbon at a second flow rate, and a third flow of oxygen (O2) at a third flow rate; ionizing the gas in the plasma chamber to generate a plasma; and exposing the substrate to the plasma, the exposing selectively etching the dielectric layer with the pattern of the patterned WxSiyNz layer to form a patterned dielectric layer.

Example 12. The method of example 11, where the fluorocarbon is a perfluorocarbon (CxFy).

Example 13. The method of one of examples 11 or 12, where the fluorocarbon is a hydrofluorocarbon (CxHyF1-x-y).

Example 14. The method of one of examples 11 to 13, where the halogen-free sulfur compound is sulfur dioxide (SO2).

Example 15. The method of one of examples 11 to 14, where the halogen-free sulfur compound is hydrogen sulfide (H2S).

Example 16. A method for etching a pattern in a layer of a substrate includes holding the substrate in a plasma chamber, the substrate including a patterned tungsten silicon nitride (WxSiyNz) layer over a dielectric layer formed on an underlayer; flowing a gas over the substrate in the plasma chamber to provide a first flow of carbonyl sulfide (COS) at a first flow rate, a second flow of a perfluorocarbon (CxFy) at a second flow rate, and a third flow of oxygen (O2) at a third flow rate; ionizing the gas in the plasma chamber to generate a plasma; and exposing the substrate to the plasma, the exposing selectively etching the dielectric layer with the pattern of the patterned WxSiyNz layer to form a patterned dielectric layer.

Example 17. The method of example 16, where the dielectric layer is a stack of alternating layers of silicon oxide and silicon nitride.

Example 18. The method of one of examples 16 or 17, where the dielectric layer is an interlayer dielectric (ILD) layer including a low dielectric constant (low-k) silicon oxide.

Example 19. The method of one of examples 16 to 18, where etching the dielectric layer exposes a surface of a conductor disposed below the dielectric layer.

Example 20. The method of one of examples 16 to 19, where the underlayer is an insulator.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method for etching a pattern in a layer of a substrate, the method comprising:
holding the substrate in a plasma chamber, the substrate comprising a patterned tungsten silicon nitride (WₓSi_{y}N_{z}) layer over a dielectric layer formed on an underlayer, the dielectric layer being a stack of alternating layers of silicon oxide and silicon nitride;
flowing a gas over the substrate in the plasma chamber to provide a first flow of carbonyl sulfide (COS) at a first flow rate, a second flow of a perfluorocarbon (CₓF_{y}) at a second flow rate, and a third flow of oxygen (O₂) at a third flow rate;
ionizing the gas in the plasma chamber to generate a plasma; and
exposing the substrate to the plasma, the exposing selectively etching the dielectric layer with the pattern of the patterned WₓSi_{y}N_{z} layer to form a patterned dielectric layer.

2. The method of claim 1,
wherein a ratio of the first flow rate to the second flow rate is between 1:10 and 1:30, and
wherein a ratio of the first flow rate to the third flow rate is between 1:5 and 1:15.

3. The method of claim 1, wherein the first flow rate is greater than or equal to 3 sccm and less than or equal to 5 sccm.

4. The method of claim 1, wherein selectively etching the dielectric layer comprises etching the dielectric layer with a first etch rate and etching the patterned WₓSi_{y}N_{z} layer with a second etch rate, a ratio of the first etch rate to the second etch rate being greater than or equal to 4 and less than or equal to 10.

5. The method of claim 1, wherein the underlayer comprises silicon nitride.

6. The method of claim 1,
wherein selectively etching the dielectric layer exposes a surface of the underlayer, and
wherein, after a surface of the underlayer is exposed, a ratio of an etch rate of the dielectric layer to an etch rate of the underlayer is greater than or equal to 1 and less than or equal to 100.

7. The method of claim 6, wherein exposing a surface of the underlayer generates an endpoint signal which, when detected, initiates a termination of etching the dielectric layer.

8. The method of claim 1, wherein an opening in the patterned dielectric layer has a width dimension and a depth dimension, the width being between 10 nm and 100 nm, and a ratio of the depth to the width being greater than 50 and less than 200.

9. The method of claim 1, wherein the patterned dielectric layer has a plurality of openings, each opening shaped like a circle having a circularity defined as a ratio of a minimum diameter to a maximum diameter of the opening, the plurality of openings having an average circularity greater than or equal to 0.9 and less than or equal to 1.

10. The method of claim 1, wherein the patterned dielectric layer has a plurality of openings, each opening having a fixed designed width, the plurality of openings having a local critical dimension uniformity (LCDU) greater than or equal to 1 nm and less than or equal to 2 nm.

11. A method for etching a pattern in a layer of a substrate, the method comprising:
holding the substrate in a plasma chamber, the substrate comprising a patterned tungsten silicon nitride (WₓSi_{y}N_{z}) layer over a dielectric layer formed on an underlayer, the dielectric layer being a stack of alternating layers of silicon oxide and silicon nitride;
flowing a gas over the substrate in the plasma chamber to provide a first flow of a halogen-free sulfur compound at a first flow rate, a second flow of a fluorocarbon at a second flow rate, and a third flow of oxygen (O₂) at a third flow rate;
ionizing the gas in the plasma chamber to generate a plasma; and
exposing the substrate to the plasma, the exposing selectively etching the dielectric layer with the pattern of the patterned WₓSi_{y}N_{z} layer to form a patterned dielectric layer.

12. The method of claim 11, wherein the fluorocarbon is a perfluorocarbon (CₓF_{y}).

13. The method of claim 11, wherein the fluorocarbon is a hydrofluorocarbon (CₓH_{y}F_{1-x-y}).

14. The method of claim 11, wherein the halogen-free sulfur compound is sulfur dioxide (SO₂).

15. The method of claim 11, wherein the halogen-free sulfur compound is hydrogen sulfide (H₂S).

16. A method for etching a pattern in a layer of a substrate, the method comprising:
holding the substrate in a plasma chamber, the substrate comprising a patterned tungsten silicon nitride (WₓSi_{y}N_{z}) layer over a dielectric layer formed on an underlayer;
flowing a gas over the substrate in the plasma chamber to provide a first flow of carbonyl sulfide (COS) at a first flow rate, a second flow of a perfluorocarbon (CₓF_{y}) at a second flow rate, and a third flow of oxygen (O₂) at a third flow rate;
ionizing the gas in the plasma chamber to generate a plasma; and
exposing the substrate to the plasma, the exposing selectively etching the dielectric layer with the pattern of the patterned WₓSi_{y}N_{z} layer to form a patterned dielectric layer.

17. The method of claim 16, wherein the dielectric layer is a stack of alternating layers of silicon oxide and silicon nitride.

18. The method of claim 16, wherein the dielectric layer is an interlayer dielectric (ILD) layer comprising a low dielectric constant (low-k) silicon oxide.

19. The method of claim 18, wherein etching the dielectric layer exposes a surface of a conductor disposed below the dielectric layer.

20. The method of claim 16, wherein the underlayer is an insulator.
